(19) United States
(12) Patent Application Publication
(10) Pub. No.: US 2024/0186953 A1
(43) Pub. Date: Jun. 6, 2024

(54) METHOD AND APPARATUS FOR POWER AMPLIFIER COMPENSATION

(71) Applicant: Telefonaktiebolaget LM Ericsson (publ), Stockholm (SE)

(72) Inventor: Weixuan HU, Beijing (CN)

(73) Assignee: Telefonaktiebolaget LM Ericsson (publ), Stockholm (SE)

(21) Appl. No.: 18/285,522

(22) PCT Filed: Apr. 9, 2021
(86) PCT No.: PCT/CN2021/086132

§ 371 Date: Oct. 4, 2023

(51) Int. Cl. H03F 1/02; H03F 3/24

(52) U.S. Cl. CPC H03F 1/0205; H03F 3/245; H03F 2200/451

(57) ABSTRACT

The present disclosure provides a method (200) for power amplifier compensation. The method (200) includes: determining (210) a compensation value for each of a plurality of power ranges; determining (220) one of the plurality of power ranges to which transmission power of an initial symbol belongs; and compensating (230) the initial symbol with the compensation value for the one power range to obtain a compensated symbol. for transmission after passing through a power amplifier.

### TECHNICAL FIELD

The present disclosure relates to communication technology, and more particularly, to a method and an apparatus for power amplifier compensation.

### BACKGROUND

GaN Power Amplifiers (PAs) have advantages in high power efficiency and loose thermal sink requirement, and are expected to be widely used. One of GaN's disadvantages, however, is the so-called trapping effect. The trapping effect is generally resulted from presence of impurities or defects in a crystalline material, which are heavily related to the GaN's epitaxial growth and surface treatment process. Electrically active crystal defects can trap electrons, leading to a fast capture (voltage driven) and slow release (thermal driven) during Radio Frequency (RF) stimuli. The capture rate is proportional to availability of electrons and empty traps and the release requires (thermal) energy. The trapping effects have impacts on the GaN's performance in various aspects. Buffer traps (below the gate metal) result in a shift in a threshold voltage, which can be observed in Drain-Source current (IDS)—Gate-Source voltage (VGS) characteristics, and also result in kink effect in IDS-VGS characteristics and IDS—Drain-Source voltage (VDS) characteristics. Gate-Source Surface (GSS) traps result in a shift in a peak trans-conductance, by modification of source resistance (Rs), which could be observed in IDS-VGS characteristics, and also result in a kink effect in IDS-VDS characteristics. Gate-Drain Surface (GDS) traps result in a shift in a knee of IDS-VDS characteristics by modification of Drain-Source resistance (RDS), and also a kink effect in IDS-VDS characteristics. Surface traps are considered as the main reason for current collapse.

The trapping effect will impact a gain and a phase response of a GaN PA. In order to solve this problem, a GaN booster solution can be used. At different temperature levels, a back-off value of a Peak PA and an IDS of a Main PA can be adjusted to generate a temperature compensation table (TCT) for the booster. While a lower back-off value of the Peak PA and a higher IDS of the Main PA can decrease the trapping effect, the power efficiency will be significantly degraded. Moreover, it may cost too much time to obtain the bias TCT for the GaN booster, which is inefficient.

There are some other solutions that have been proposed, which requires an additional circuit, such as a Diode based Phase Modulator circuit, as a pre-correction circuit, to pre-correct the gain and phase offset. However, such solutions have increased costs, and their performance gets worse for dynamic waveforms having small signals and large signals, e.g., for Long Term Evolution (LTE) tm2a test sequence.

### SUMMARY

It is an object of the present disclosure to provide a method and an apparatus for PA compensation, capable of solving or at least mitigating at least one of the above problems.

According to a first aspect of the present disclosure, a method for power amplifier compensation. The method includes: determining a compensation value for each of a plurality of power ranges; determining one of the plurality of power ranges to which transmission power of an initial symbol belongs; and compensating the initial symbol with the compensation value for the one power range to obtain a compensated symbol, for transmission after passing through a power amplifier.

In an embodiment, the respective compensation values for the plurality of power ranges may be maintained in a look-up table, and the compensation value for the one power range may be determined from the look-up table.

In an embodiment, the plurality of power ranges may be obtained by dividing a power dynamic range of a transmission symbol linearly or non-linearly.

In an embodiment, the method may further include: obtaining a symbol as a result of the compensated symbol transmitted after passing through the power amplifier and received by means of coupling; and updating the compensation value for the one power range based on the obtained symbol.

In an embodiment, the operation of updating may include: calculating an offset between the initial symbol and the obtained symbol; and updating the compensation value for the one power range based on the offset.

In an embodiment, the obtained symbol may be gain and phase adjusted before the offset is calculated.

In an embodiment, the power amplifier may be a GaN power amplifier and the respective compensation values for the plurality of power ranges may be for compensating at least a trapping effect of the power amplifier.

According to a second aspect of the present disclosure, an apparatus for power amplifier compensation is provided. The apparatus includes a processor and a memory. The memory contains instructions executable by the processor whereby the apparatus is operative to perform the method according to the above first aspect.

In an embodiment, the apparatus may be provided in a Digital Unit (DU) of a network device, and the power amplifier may be provided in a Radio Unit (RU) of the network device.

According to a third aspect of the present disclosure, a computer readable storage medium is provided. The computer readable storage medium has computer program instructions stored thereon. The computer program instructions, when executed by a processor in an apparatus for power amplifier compensation, cause the apparatus to perform the method according to the above first aspect.

With the embodiments of the present disclosure, a symbol based solution is introduced for power amplifier compensation, including, but not limited to, compensation of the trapping effect of the power amplifier. According to the embodiments of the present disclosure, no GaN booster or GaN TCT is required, no power efficiency loss will be caused, and no additional hardware is needed, while achieving better power amplifier performance especially for dynamic waveforms such as the LTE tm2a test sequence.

### BRIEF DESCRIPTION OF THE DRAWINGS

The above and other objects, features and advantages will be more apparent from the following description of embodiments with reference to the figures, in which:

FIG. 1 is a block diagram of a network device in which the embodiments of the present disclosure can be applied.

FIG. 2 is a flowchart illustrating a method for power amplifier compensation according to an embodiment of the present disclosure;

FIG. 3 is a schematic diagram showing a compensating process and an updating process according to an embodiment of the present disclosure;

FIGS. 4A and 4B are schematic diagrams showing measurement results without and with the compensation according to the present disclosure, respectively;

FIG. 5 is a schematic diagram showing convergence of updating iterations;

FIG. 6 is a block diagram of an apparatus for power amplifier compensation according to an embodiment of the present disclosure; and

FIG. 7 is a block diagram of an apparatus for power amplifier compensation according to another embodiment of the present disclosure.

### DETAILED DESCRIPTION

In the following description and claims, unless defined otherwise, all technical and scientific terms used herein have the same meaning as commonly understood by one of ordinary skills in the art to which this disclosure belongs.

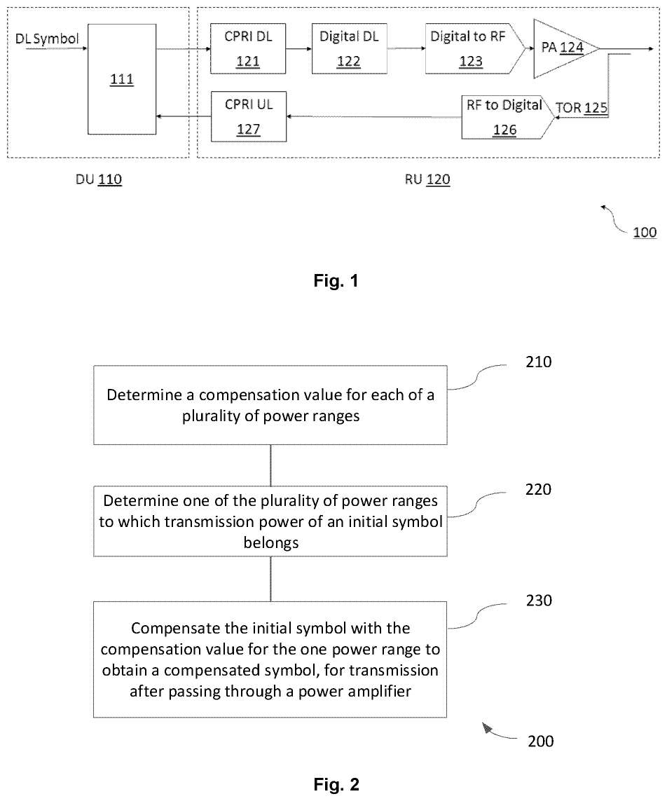

FIG. 1 is a block diagram of a network device 100 in which the embodiments of the present disclosure can be applied. The network device 100 may be e.g., or a (next) generation NodeB (gNB). The network device 100 includes a Digital Unit (DU) 110 and a Radio Unit (RU) 120. The DU 110 includes an apparatus 111 for power amplifier compensation, where a downlink (DL) symbol is pre-processed before being delivered to the RU 120 via a DL Common Public Radio Interface (CPRI) 121. The DL symbol is then digital processed at a digital processor 122, converted into an RF symbol at a digital to RF converter 123, amplified by a PA 124, and transmitted over an air interface. The transmitted symbol is received by a Transmission Observation Receiver (TOR) 125, converted into a digital symbol at an RF to digital converter 126, and delivered to the DU 110 (in particular the apparatus 111) via an uplink (UL) CPRI 127. The operations of the apparatus 111 will be described hereinafter.

FIG. 2 is a flowchart illustrating a method 200 for power amplifier compensation according to an embodiment of the present disclosure. The method 200 can be performed by e.g., the apparatus 111 in FIG. 1.

At block 210, a compensation value for each of a plurality of power ranges is determined.

Here, the plurality of power ranges can be obtained by dividing a power dynamic range of a transmission symbol (e.g., a possible power dynamic range of the DL symbol in FIG. 1) linearly or non-linearly (e.g., logarithmically).

At block 220, one of the plurality of power ranges to which transmission power of an initial symbol (e.g., the DL symbol in FIG. 1) belongs is determined.

In an example, the respective compensation values for the plurality of power ranges may be maintained in a look-up table. The compensation value for the one power range may be determined from the look-up table.

At block 230, the initial symbol is compensated with the compensation value for the one power range to obtain a compensated symbol, for transmission after passing through a power amplifier, e.g., the PA 124 in FIG. 1. Here, the power amplifier may be e.g., a GaN PA, and the respective compensation values for the plurality of power ranges may be for compensating at least a trapping effect of the GaN PA.

In an example, a symbol as a result of the compensated symbol transmitted after passing through the power amplifier and received by means of coupling (e.g., by the TOR 125 in FIG. 1) can be obtained. Then, the compensation value for the one power range can be updated based on the obtained symbol. In particular, an offset between the initial symbol and the obtained symbol can be calculated, and the compensation value for the one power range can be updated based on the offset. In an example, the obtained symbol can be gain and phase adjusted, for alignment with respect to the initial symbol, before the offset is calculated.

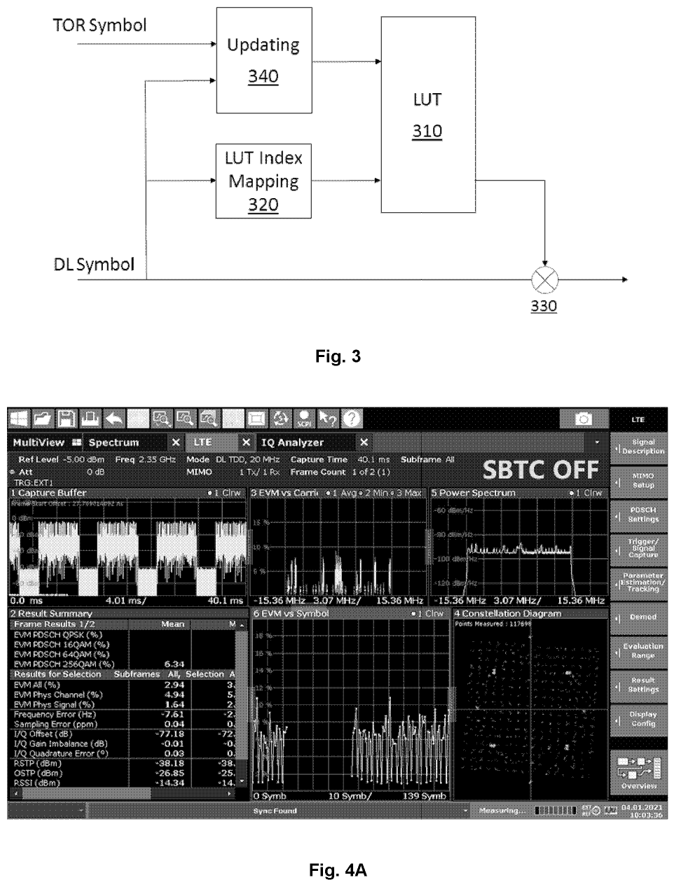

The method 200 will be explained in further detail below with reference to FIG. 3, which shows a compensating process and an updating process according to an embodiment of the present disclosure.

As shown in FIG. 3, a look-up table (LUT) 310 is provided. For a DL symbol (initial symbol), its transmission power is mapped to an LUT index at 320. For the LUT index mapping, the transmission power is calculated according to:

power=Σₖ₌₀^{L-1}(I²(k)+Q²(k)) (1)

where k is a sample index, L is the number of samples in the symbol, I(k) denotes a magnitude of an in-phase component of the sample having the sample index k, and Q(k) denotes a magnitude of a quadrature component of the sample having the sample index k.

The possible power dynamic range of the DL symbol can be divided, linearly or non-linearly (e.g., logarithmically), into a number (e.g., 4, 8, 16, or any other appropriate number) of power ranges. The LUT index corresponding to the DL symbol can be determined as:

Index=f(power) (2)

where Index denotes the LUT index and f( ) denotes a function for mapping the transmission power to the LUT index.

The LUT index, Index, is inputted to the LUT 310 to obtain a compensation value corresponding to the LUT index, denoted as LUT(Index).

Then, the DL symbol is compensated with the compensation value at a multiplier 330 according to:

pre_Tx=Tx*LUT (Index) (3)

where pre_Tx denotes the compensated (or preprocessed) symbol, Tx denotes the DL symbol, and LUT(Index) denotes the compensation value.

The compensated symbol outputted from the multiplier 330 is delivered to an RU (e.g., the RU 120 in FIG. 1), where it is transmitted after passing through a power amplifier (e.g., the PA 124 in FIG. 1). The transmitted symbol is received by a TOR (e.g., the TOR 125 in FIG. 1) and the received symbol is denoted as TOR symbol in FIG. 3. The TOR symbol is inputted, along with the DL symbol, for updating iteration of the compensation value at 340.

First of all, the delay between the DL symbol and the TOR symbol, the phase and gain offsets between the DL symbol and the TOR symbol, and the normalization of the TOR symbol can be done at any power level for alignment. Initially, all the compensation values in the LUT 310 can be set to be 1, and an updating coefficient W_{M}(i) can be set to 1 for i=0,1,2 . . . Dep−1 and M=0, where Dep denotes the depth (i.e., number of indices) of the LUT 310, and M denotes an updating iteration number and equals 0 initially. Each iteration may involve a number of symbols.

An offset between the DL symbol and the TOR symbol can be calculated as:

$$OST = \frac{{\sum }_{k = 0}^{L - 1} {\vert Tx ( k ) \vert}^{2}}{{\sum }_{k = 0}^{L - 1} Tor ( k ) . * conj ( Tx ( k ) )} \qquad ( 4 )$$

where OST(Index) denotes the offset corresponding to the LUT index, Tx(k) denotes a magnitude of the sample having the sample index k in the DL symbol, Tor(k) denotes a magnitude of the sample having the sample index k in the TOR symbol, and conj( ) denotes a conjugate operation.

The updating coefficient corresponding to the LUT index can be calculated as:

W_{M}(index)=W_{M}(index)*(1−α)+OST(index)*α (5)

where α is a weight, and W_{M} (index) is the updating coefficient in a shadow LUT used for offline updating during one iteration (M-th iteration). After the M-th iteration, the LUT 310 can be updated according to:

LUT_{M+1}(i)=LUT_{M}(i)*W_{M}(i) (6)

where LUT_{M+1}(i) denotes the compensation value corresponding to the LUT index i in the LUT 310 at the (M+1)-th iteration, and LUT_{M}(i) denotes the compensation value corresponding to the LUT index i in the LUT 310 at the M-th iteration.

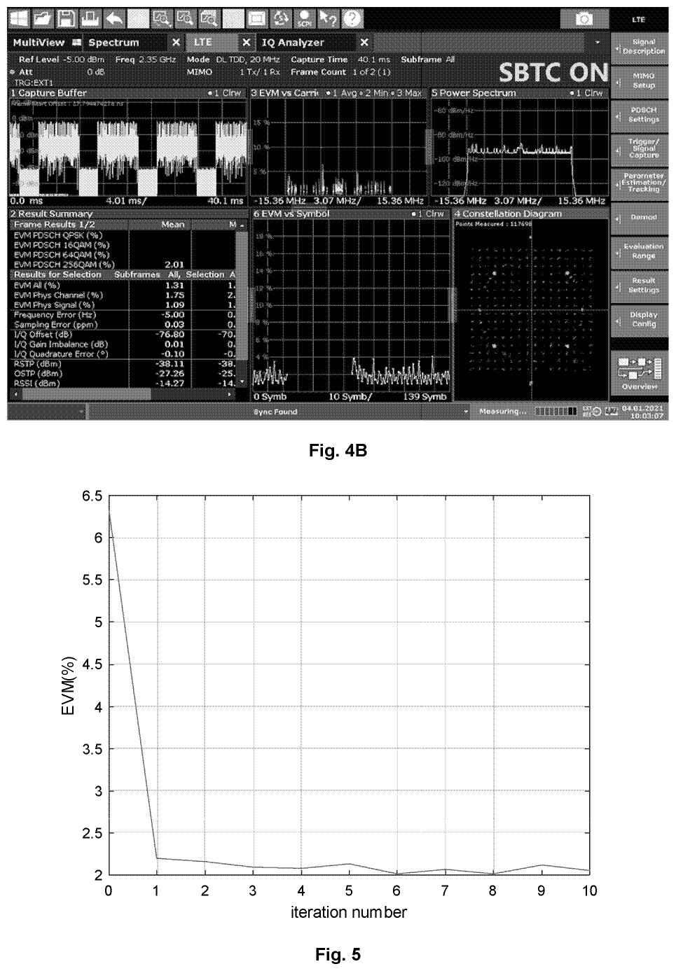

FIGS. 4A and 4B show measurement results for a classic macro radio product based on the LTE tm2a test sequence without and with the compensation (shown as Symbol Based Trapping Compensation (SBTC)) according to the present disclosure, respectively. An LUT depth of 16 is assumed in the measurement. In FIG. 4A, without the compensation according to the present disclosure, the Error Vector Magnitude (EVM) is 6.34%. In FIG. 4B, with the compensation according to the present disclosure, the EVM is reduced to 2.01%, which meets the required EVM of 3.5% for the LTE tm2a test sequence.

Table 1 below shows measurement results based on different types of signals. Here, two carriers each having a bandwidth of 20 MHz are used in the measurement. It can be seen that, when both carriers carry the LTE tm2a test sequence (dynamic signals), with the compensation according to the present disclosure, the EVM can be reduced significantly. When either carrier carries an LTE tm3p1 test sequence (static signals), the EVM performance does not degrade with the compensation according to the present disclosure.

TABLE 1

| Carrier 1/ | EVM (%) without | EVM (%) with |
|---|---|---|
| Carrier 2 | compensation | compensation |
| tm2a/tm2a | 6.05/5.82 | 2.29/2.33 |
| tm3p1/tm2a | 1.42/1.26 | 1.42/1.26 |
| tm3p1/tm3p1 | 3.9/3.88 | 3.9/3.88 |

FIG. 5 is a schematic diagram showing convergence of updating iterations. It can be seen that after one iteration, the EVM is reduced to approximately 2.2% and keeps stable as the updating iterates.

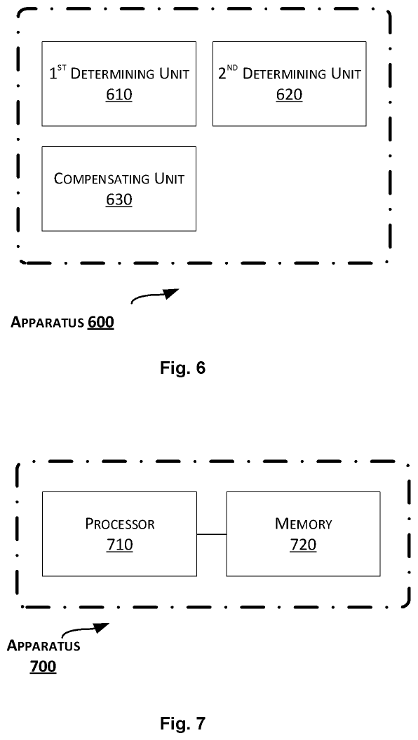

Correspondingly to the method 200 as described above, an apparatus for power amplifier compensation is provided. FIG. 6 is a block diagram of an apparatus 600 for power amplifier compensation according to an embodiment of the present disclosure.

The apparatus 600 can be operative to perform the method 200 as described above in connection with FIG. 2. As shown in FIG. 6, the apparatus 600 includes a first determining unit 610 configured to determine a compensation value for each of a plurality of power ranges. The apparatus 600 further includes a second determining unit 620 configured to determine one of the plurality of power ranges to which transmission power of an initial symbol belongs. The apparatus 600 further includes a compensating unit 630 configured to compensate the initial symbol with the compensation value for the one power range to obtain a compensated symbol, for transmission after passing through a power amplifier.

In an embodiment, the respective compensation values for the plurality of power ranges may be maintained in a look-up table, and the compensation value for the one power range may be determined from the look-up table.

In an embodiment, the plurality of power ranges may be obtained by dividing a power dynamic range of a transmission symbol linearly or non-linearly.

In an embodiment, the apparatus 600 may further include an obtaining unit configured to obtain a symbol as a result of the compensated symbol transmitted after passing through the power amplifier and received by means of coupling. The apparatus 600 may further include an updating unit configured to update the compensation value for the one power range based on the obtained symbol.

In an embodiment, the updating unit may be configured to: calculate an offset between the initial symbol and the obtained symbol; and update the compensation value for the one power range based on the offset.

In an embodiment, the obtained symbol may be gain and phase adjusted before the offset is calculated.

In an embodiment, the power amplifier may be a GaN power amplifier and the respective compensation values for the plurality of power ranges may be for compensating at least a trapping effect of the power amplifier.

In an embodiment, the apparatus 600 can be provided in a DU (e.g., the DU 110 in FIG. 1) of a network device (e.g., the network device 100 in FIG. 1), and the power amplifier can be provided in an RU (e.g., the RU 120 in FIG. 1) of the network device.

The first determining unit 610, the second determining unit 620, and the updating unit 630 can be implemented as a pure hardware solution or as a combination of software and hardware, e.g., by one or more of: a processor or a micro-processor and adequate software and memory for storing of the software, a Programmable Logic Device (PLD) or other electronic component(s) or processing circuitry configured to perform the actions described above, and illustrated, e.g., in FIG. 2.

FIG. 7 is a block diagram of an apparatus 700 for power amplifier compensation according to another embodiment of the present disclosure.

The apparatus 700 includes a processor 710 and a memory 720. The memory 720 contains instructions executable by the processor 710 whereby the apparatus 700 is operative to perform the actions, e.g., of the procedure described earlier in conjunction with FIG. 2. Particularly, the memory 720 contains instructions executable by the processor 710 whereby the apparatus 700 is operative to: determine a compensation value for each of a plurality of power ranges; determine one of the plurality of power ranges to which transmission power of an initial symbol belongs; and compensate the initial symbol with the compensation value for the one power range to obtain a compensated symbol, for transmission after passing through a power amplifier.

In an embodiment, the respective compensation values for the plurality of power ranges may be maintained in a look-up table, and the compensation value for the one power range may be determined from the look-up table.

In an embodiment, the plurality of power ranges may be obtained by dividing a power dynamic range of a transmission symbol linearly or non-linearly.

In an embodiment, the memory 720 may further contain instructions executable by the processor 710 whereby the apparatus 700 is operative to: obtain a symbol as a result of the compensated symbol transmitted after passing through the power amplifier and received by means of coupling; and update the compensation value for the one power range based on the obtained symbol.

In an embodiment, the operation of updating may include: calculating an offset between the initial symbol and the obtained symbol; and updating the compensation value for the one power range based on the offset.

In an embodiment, the obtained symbol may be gain and phase adjusted before the offset is calculated.

In an embodiment, the power amplifier may be a GaN power amplifier and the respective compensation values for the plurality of power ranges may be for compensating at least a trapping effect of the power amplifier.

In an embodiment, the apparatus 700 can be provided in a DU (e.g., the DU 110 in FIG. 1) of a network device (e.g., the network device 100 in FIG. 1), and the power amplifier can be provided in an RU (e.g., the RU 120 in FIG. 1) of the network device.

The present disclosure also provides at least one computer program product in the form of a non-volatile or volatile memory, e.g., a non-transitory computer readable storage medium, an Electrically Erasable Programmable Read-Only Memory (EEPROM), a flash memory and a hard drive. The computer program product includes a computer program. The computer program includes: code/computer readable instructions, which when executed by the processor 710 causes the apparatus 700 to perform the actions, e.g., of the procedure described earlier in conjunction with FIG. 2.

The computer program product may be configured as a computer program code structured in computer program modules. The computer program modules could essentially perform the actions of the flow illustrated in FIG. 2.

The processor may be a single CPU (Central Processing Unit), but could also comprise two or more processing units. For example, the processor may include general purpose microprocessors; instruction set processors and/or related chips sets and/or special purpose microprocessors such as Application Specific Integrated Circuits (ASICs). The processor may also comprise board memory for caching purposes. The computer program may be carried by a computer program product connected to the processor. The computer program product may comprise a non-transitory computer readable storage medium on which the computer program is stored. For example, the computer program product may be a flash memory, a Random-Access Memory (RAM), a Read-Only Memory (ROM), or an EEPROM, and the computer program modules described above could in alternative embodiments be distributed on different computer program products in the form of memories.

The disclosure has been described above with reference to embodiments thereof. It should be understood that various modifications, alternations and additions can be made by those skilled in the art without departing from the spirits and scope of the disclosure. Therefore, the scope of the disclosure is not limited to the above particular embodiments but only defined by the claims as attached.

1. A method for power amplifier compensation, comprising:
determining a compensation value for each of a plurality of power ranges;
determining one of the plurality of power ranges to which transmission power of an initial symbol belongs; and
compensating the initial symbol with the compensation value for the one power range to obtain a compensated symbol, for transmission after passing through a power amplifier.

2. The method of claim 1, wherein the respective compensation values for the plurality of power ranges are maintained in a look-up table, and the compensation value for the one power range is determined from the look-up table.

3. The method of claim 1, wherein the plurality of power ranges are obtained by dividing a power dynamic range of a transmission symbol linearly or non-linearly.

4. The method of claim 1, further comprising:
obtaining a symbol as a result of the compensated symbol transmitted after passing through the power amplifier and received by means of coupling; and
updating the compensation value for the one power range based on the obtained symbol.

5. The method of claim 4, wherein said updating comprises:
calculating an offset between the initial symbol and the obtained symbol; and
updating the compensation value for the one power range based on the offset.

6. The method of claim 5, wherein the obtained symbol is gain and phase adjusted before the offset is calculated.

7. The method of claim 1, wherein the power amplifier is a GaN power amplifier and the respective compensation values for the plurality of power ranges are for compensating at least a trapping effect of the power amplifier.

8. An apparatus for power amplifier compensation, comprising a processor and a memory, the memory comprising instructions executable by the processor wherein the apparatus is operative to perform the method of claim 1.

9. The apparatus of claim 8, wherein the apparatus is provided in a Digital Unit of a network device, and the power amplifier is provided in a Radio Unit of the network device.

10. A computer readable storage medium having computer program instructions stored thereon, the computer program instructions, when executed by a processor in an apparatus for power amplifier compensation, causing the apparatus to perform the method of claim 1.
